(19) United States
(12) Patent Application Publication
(10) Pub. No.: US 2026/0282273 A1
(43) Pub. Date: Sep. 17, 2026

(54) LIQUID IMMERSION DEVICE AND CONTROL METHOD THEREOF

(71) Applicant: Kioxia Corporation, Tokyo (JP)

(72) Inventors: Tomofumi HORIUCHI, Yokohama (JP); Koichi SATO, Yokohama (JP); Takuma KOJIMA, Tokyo (JP); Takeaki SERIZAWA, Hiratsuka (JP); Kaori OTA, Yokohama (JP); Hiroshi MITSUGI, Tokyo (JP)

(73) Assignee: Kioxia Corporation, Tokyo (JP)

(21) Appl. No.: 19/332,424

(22) Filed: Sep. 18, 2025

(30) Foreign Application Priority Data
Mar. 14, 2025 (JP) 2025-041741

(51) Int. Cl. H05K 7/20

(52) U.S. Cl. CPC H05K 7/20236; H05K 7/20272; H05K 7/20281

(57) ABSTRACT

According to one embodiment, a liquid immersion device includes a housing capable of accommodating a liquid and a semiconductor device immersed in the liquid. A plurality of semiconductor device controllers are provided on an outside of the housing and are capable of controlling the semiconductor device. A connector is attachably and detachably connected to the semiconductor device inside the housing, is attachably and detachably connected to any of the plurality of semiconductor device controllers outside the housing, and electrically connects the semiconductor device and a semiconductor device controller.

### CROSS-REFERENCE TO RELATED APPLICATION

This application is based upon and claims the benefit of priority from Japanese Patent Application No. 2025-041741, filed Mar. 14, 2025, the entire contents of which are incorporated herein by reference.

### FIELD

Embodiments described herein relate generally to a liquid immersion device and a control method thereof.

### BACKGROUND

In a control device of a semiconductor test device or the like, a semiconductor device may be immersed in a liquid to control a test or the like. In a control step of such a semiconductor device, when a plurality of different controls are executed on the semiconductor device, it is necessary to remove the semiconductor device from a control device and mount the semiconductor device on another control device each time the control is changed. Such a change in the control device causes an increase in the load on the operator and an extension of the manufacturing turnaround time (TAT) including a plurality of tests.

### DESCRIPTION OF THE DRAWINGS

FIG. 1 is a front view showing a configuration example of a liquid immersion device according to a first embodiment.

FIG. 2 is a side view showing a configuration example of the liquid immersion device according to the first embodiment.

FIG. 3 is a rear view showing a configuration example of the liquid immersion device according to the first embodiment.

FIG. 4A is a perspective view showing a configuration example of a connection unit (e.g., connector).

FIG. 4B is a conceptual diagram showing a configuration example of the connection unit.

FIG. 4C is a conceptual diagram when the connection unit is attached to a wall surface of a housing.

FIG. 4D is a conceptual diagram showing a state in which the connection unit is attached to the wall surface of the housing.

FIG. 4E is a conceptual diagram showing a state in which the connection unit is attached to the wall surface of the housing.

FIG. 5 is a flowchart showing an example of a control method of the liquid immersion device according to the first embodiment.

FIG. 6 is a cross-sectional view showing an example of the control method of the liquid immersion device according to the first embodiment.

FIG. 7 is a cross-sectional view showing the control method of the liquid immersion device, following FIG. 6.

FIG. 8 is a cross-sectional view showing the control method of the liquid immersion device, following FIG. 7.

FIG. 9 is a cross-sectional view showing the control method of the liquid immersion device, following FIG. 8.

FIG. 10 is a perspective view showing the control method of the liquid immersion device.

FIG. 11 is a cross-sectional view showing the control method of the liquid immersion device, following FIG. 9.

FIG. 12 is a cross-sectional view showing the control method of the liquid immersion device, following FIG. 11.

FIG. 13 is a cross-sectional view showing the control method of the liquid immersion device, following FIG. 12.

### DETAILED DESCRIPTION

Embodiments provide a liquid immersion device and a control method thereof capable of reducing a burden on an operator and shortening a control time of a test or the like.

In general, according to one embodiment, a liquid immersion device includes a housing capable of accommodating a liquid and a semiconductor device immersed in the liquid. A plurality of control units (e.g., semiconductor device controller) are provided on an outside of the housing and are capable of controlling the semiconductor device. A connection unit (e.g., connector) is attachably and detachably connected to the semiconductor device inside the housing, is attachably and detachably connected to any of the plurality of control units outside the housing, and electrically connects the mounted semiconductor device and the mounted control unit.

Hereinafter, embodiments of the present disclosure will be described with reference to the drawings. The present embodiment does not limit the present disclosure. The position and size of the shown component are an example and may be changed. In the specification and drawings, the same elements are denoted by the same reference numerals.

### First Embodiment

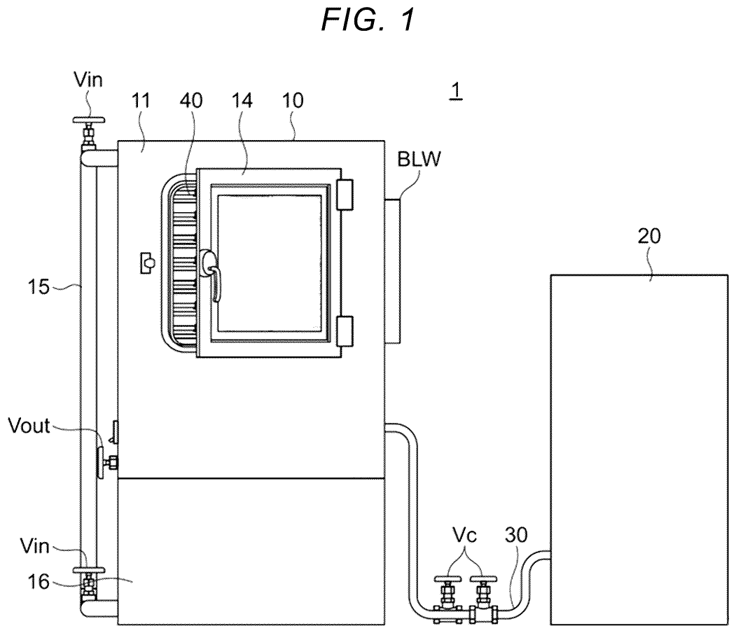

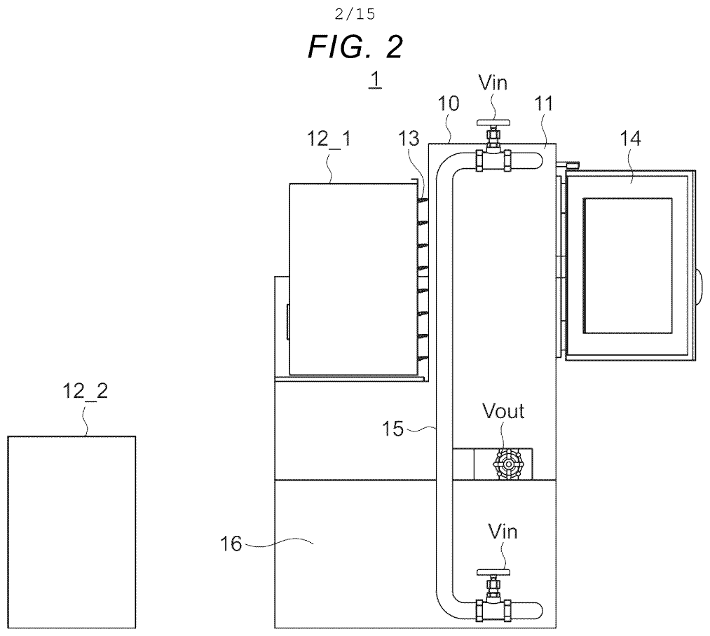

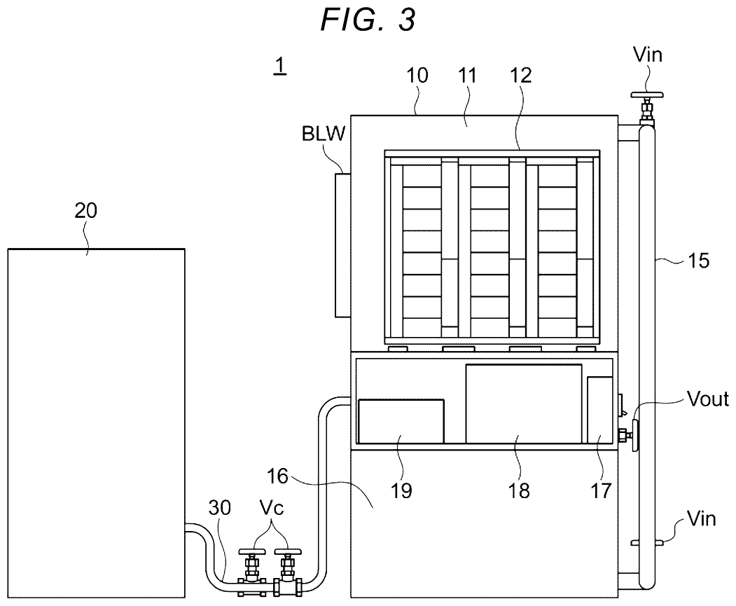

FIG. 1 is a front view showing a configuration example of a liquid immersion device according to a first embodiment. FIG. 2 is a side view showing a configuration example of the liquid immersion device according to the first embodiment. FIG. 3 is a rear view showing a configuration example of the liquid immersion device according to the first embodiment.

A liquid immersion device 1 according to the first embodiment includes a liquid immersion unit 10, a temperature control unit 20 (e.g., temperature controller), and a pipe 30. For example, the liquid immersion device 1 may be a semiconductor test device that performs an electrical test of the semiconductor device 40. For example, the liquid immersion device 1 may be an information processing device that controls the semiconductor device 40 to perform various information processing. The semiconductor device 40 may be a memory product using, for example, a NAND flash memory such as a solid state drive (SSD). For example, the semiconductor device 40 may be a semiconductor product using a central processing unit (CPU) or the like.

The liquid immersion unit 10 includes a housing 11, a control unit (e.g., semiconductor device controller) 12 (a control unit 12_1 and a control unit 12_2), a connection unit 13, a door 14, a pipe 15, a liquid storage unit (e.g., liquid storage or storage) 16, pumps 17 and 19, a controller 18, and a blower BLW.

The housing 11 has a space capable of accommodating one or a plurality of semiconductor devices 40 therein. The housing 11 can store a liquid and can immerse the semiconductor device 40 in the liquid.

The housing 11 is provided with the door 14. The operator can open the door 14 and carry the semiconductor device 40 into the housing 11 or remove the semiconductor device 40 from the housing 11. When the door 14 is closed, the door 14 can be closed in a liquid-tight state with respect to an opening of the housing 11 so that the housing 11 can store the liquid.

A plurality of control units 12_1 and 12_2 are provided on the outside of the housing 11 as shown in FIG. 2. Each of the control units 12_1 and 12_2 performs different controls on the semiconductor device 40. For example, each of the control units 12_1 and 12_2 executes a first test and a second test, which are different from each other, on the semiconductor device 40. One of the plurality of control units 12_1 and 12_2 is mounted on a rear surface side of the housing 11 opposite to the door 14. The control unit 12 mounted on the housing 11 controls the semiconductor device 40. FIG. 2 shows a state in which the control unit 12_1 is mounted on the housing 11. Although FIG. 2 shows two control units 12_1 and 12_2, the number of control units 12 may be three or more.

The connection unit 13 penetrates a wall portion of the housing 11 in a liquid-tight state. The connection unit 13 is attachably and detachably connected to the semiconductor device 40 inside the housing 11 and is attachably and detachably connected to any of the plurality of control units 12_1 and 12_2 outside the housing 11. The connection unit 13 electrically connects the mounted semiconductor device 40 and the mounted control unit 12 (for example, the control unit 12_1). As a result, the mounted control unit 12 can control the semiconductor device 40 for a test or the like. The connection unit 13 is provided on a rear surface side of the housing 11 opposite to the door 14.

For example, among the plurality of control units 12_1 and 12_2, the control unit 12_1 is mounted on the connection unit 13 to perform a first control (for example, a first test) of the semiconductor device 40. While the semiconductor device 40 is in a state of being immersed in the liquid inside the housing 11, the control unit 12_1 is detached from the connection unit 13, and the control unit 12_2 is mounted on the connection unit 13 to perform a second control (for example, a second test) of the semiconductor device 40. As a result, the liquid immersion device 1 can continuously execute a plurality of controls (for example, a plurality of tests) on the semiconductor device 40 by using the plurality of control units 12_1 and 12_2 while the semiconductor device 40 is in a state of being immersed in the liquid in the housing 11.

The pipe 15 is connected between the liquid storage unit 16 and the housing 11 in order to supply the liquid from the liquid storage unit 16 to the housing 11. A valve Vin is provided in the pipe 15. The valve Vin is opened when the liquid is supplied to the housing 11.

The liquid storage unit 16 stores a liquid supplied to the housing 11 or extracted from the housing 11. The liquid storage unit 16 is separated from the housing 11 that accommodates the semiconductor device 40. The liquid storage unit 16 is connected to the housing 11 by the pipe 15 and an internal pipe (not shown). A valve Vout is provided in the internal pipe. The valve Vout is opened when the liquid is drawn from the housing 11 to the liquid storage unit 16.

As described above, when the liquid is supplied from the liquid storage unit 16 to the housing 11, the valve Vin is opened, and the liquid is supplied to the housing 11 via the pipe 15. When the liquid is returned from the housing 11 to the liquid storage unit 16, the valve Vout is opened, and the liquid is returned to the liquid storage unit 16 via the internal pipe.

The liquid is an insulating medium that cools or heats the semiconductor device 40. For example, the liquid may be a mineral oil or a vegetable oil.

The pump 17 is provided in the housing 11 or the liquid storage unit 16. Since the liquid storage unit 16 is provided at a position lower than the housing 11 (directly below the housing 11), when the liquid is supplied from the liquid storage unit 16 to the housing 11, the pump 17 sends the liquid in the liquid storage unit 16 to the pipe 15. On the other hand, when the liquid is drawn from the housing 11 to the liquid storage unit 16, the liquid falls from the housing 11 to the liquid storage unit 16 under its own weight. Therefore, a pump is not required for the internal pipe. In order to shorten a control process, a pump may be provided in the internal pipe to forcibly draw the liquid from the housing 11 to the liquid storage unit 16. As a result, the time for drawing the liquid can be shortened.

The blower BLW is provided in the housing 11 and blows gas into the semiconductor device 40 in the housing 11 after the liquid is extracted from the housing 11. As a result, the liquid adhering to the semiconductor device 40 can be dried in a short time.

The controller 18 controls each of the elements of the liquid immersion device 1. For example, the controller 18 controls the valves Vin, Vout, and Vc, the pump 17, the blower BLW, and the temperature control unit 20, and executes the liquid immersion and the control of the semiconductor device 40. The controller 18 may open and close the valves Vin, Vout, and Vc.

The temperature control unit 20 controls the temperature of the liquid. The temperature control unit 20 is connected to the housing 11 by the pipe 30, controls the temperature of the liquid by cooling or heating the liquid, and returns the liquid of a predetermined temperature to the housing 11. By controlling the temperature of the liquid to be returned to the housing 11, the temperature of the semiconductor device 40 in the housing 11 can be controlled.

The temperature control unit 20 may be omitted, and a plurality of liquid storage units 16 storing liquids at different temperatures may be provided. A liquid at a first temperature is filled in one of the plurality of liquid storage units 16, and a liquid at a second temperature is filled in another one of the plurality of liquid storage units 16. The first temperature and the second temperature are different from each other. The controller 18 may send liquids of different temperatures from the plurality of liquid storage units 16 into the housing 11 by executing control. As described above, even when the plurality of liquid storage units 16 storing different liquids are provided, it is possible to change and control the temperature of the semiconductor device 40 in the housing 11.

The pipe 30 is connected between the temperature control unit 20 and the housing 11 in order to circulate the liquid between the temperature control unit 20 and the housing 11. The valve Vc is provided in the pipe 30. The valve Vc is opened when the liquid is circulated between the temperature control unit 20 and the housing 11 during the control of the semiconductor device 40.

The pump 19 sends the liquid between the housing 11 and the temperature control unit 20 into the pipe 30 in order to circulate the liquid between the housing 11 and the temperature control unit 20.

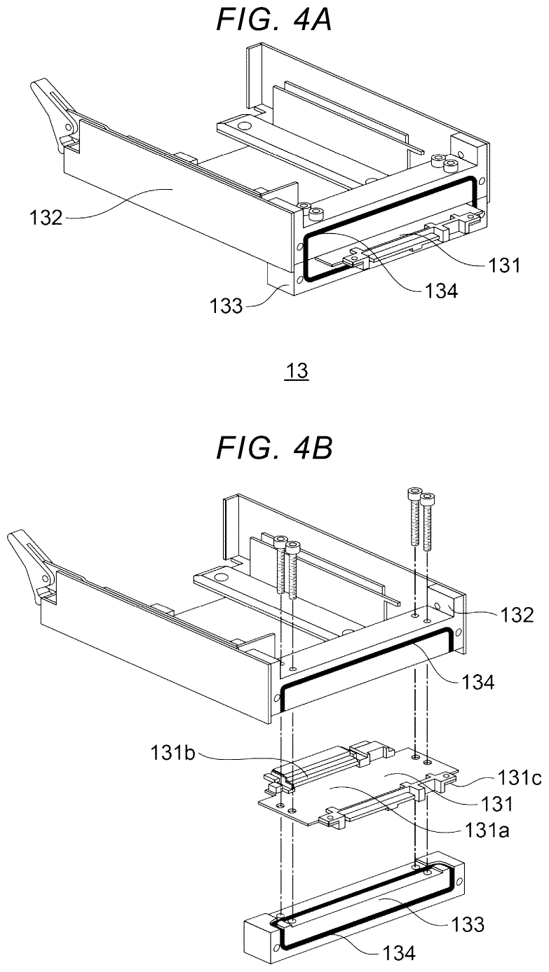

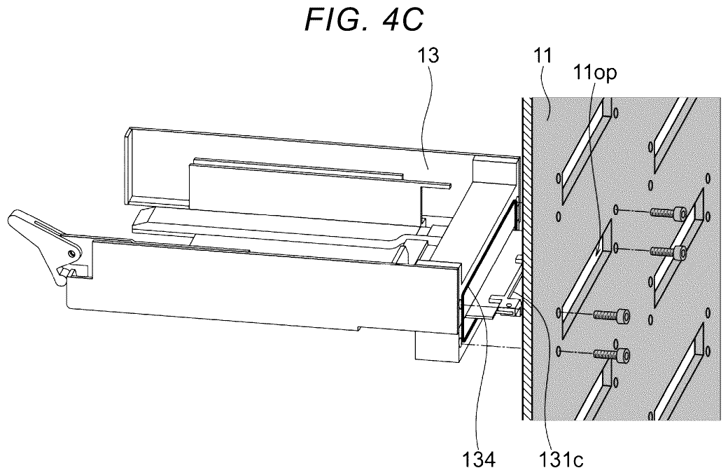

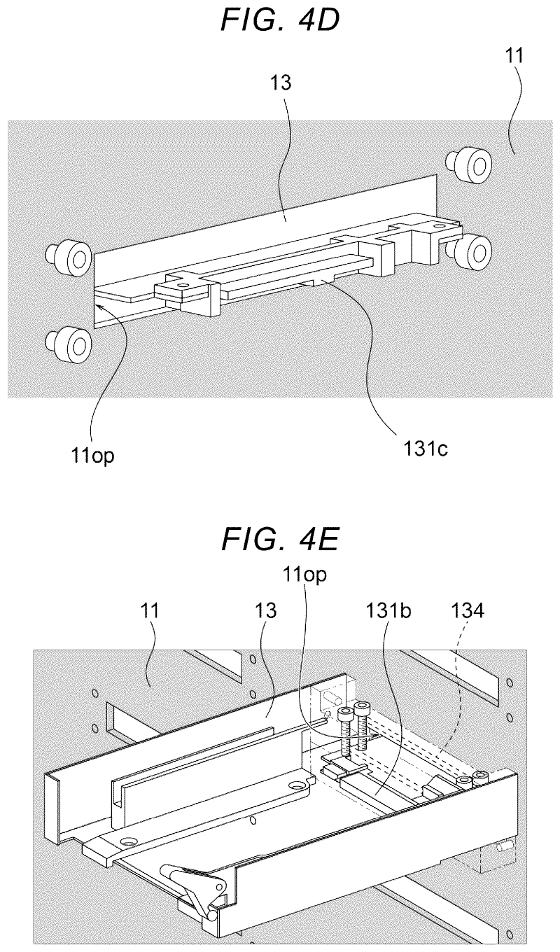

FIG. 4A is a perspective view showing a configuration example of the connection unit. FIG. 4B is a conceptual diagram showing a configuration example of the connection unit. The connection unit 13 includes a connector 131, a socket 132, a pinching member 133, and a packing 134.

As shown in FIG. 4B, the connector 131 includes a substrate 131a, an internal adapter 131in, and an external adapter 131out. For example, the substrate 131a is a circuit board. For example, a glass epoxy resin and metal wiring are used for the substrate 131a. The internal adapter 131in is an adapter that can be electrically connected to the semiconductor device 40 accommodated inside the housing 11. The external adapter 131out is an adapter that can be electrically connected to the plurality of control units 12_1 and 12_2 disposed outside the housing 11.

The socket 132 accommodates and supports the semiconductor device 40, and is provided in order to appropriately fit the semiconductor device 40 to the internal adapter 131in.

The pinching member 133 pinches the connector 131 between the pinching member 133 and the socket 132, and fixes the socket 132 to the socket 132 and the pinching member 133. As shown in FIG. 4B, the socket 132 and the pinching member 133 are screwed together with the connector 131 interposed therebetween. As a result, as shown in FIG. 4A, the connector 131, the socket 132, and the pinching member 133 constitute the integral connection unit 13. For example, an insulating member such as resin is used for the socket 132 and the pinching member 133.

The packing 134 as a sealing material surrounds the periphery of the connector 131 at the end surfaces of the connector 131 and the pinching member 133 in contact with the housing 11. For example, a resin having a certain degree of flexibility such as rubber or silicone is used for the packing 134. When the connection unit 13 is attached to the housing 11, the packing 134 is pressed between the end surfaces of the connector 131 and the pinching member 133 and the inner wall surface of the housing 11 to isolate the connector 131 from the inside of the housing 11 in a liquid-tight state or an air-tight state. In addition, the packing 134 is pressed against the substrate 131a between an internal connector 131b and an external connector 131c to isolate the internal connector 131b and the external connector 131c in a liquid-tight state or an air-tight state.

FIG. 4C is a conceptual diagram when the connection unit is attached to the wall surface of the housing. FIGS. 4D and 4E are conceptual diagrams showing a state in which the connection unit is attached to the wall surface of the housing. The connection unit 13 is attached to an opening 11op provided in the wall portion of the housing 11. The external connector 131c penetrates the opening 11op from the inside of the housing 11 to the outside. The connection unit 13 is screwed to the wall portion of the housing 11 in a state where the external connector 131c is inserted into the opening 11op. As shown in FIG. 4D, the external connector 131c penetrates the wall surface of the housing 11 and is exposed to the outside of the housing 11. On the other hand, the internal connector 131b is left inside the housing 11 as shown in FIG. 4E. As a result, the connection unit 13 can electrically connect the semiconductor device 40 mounted on the internal connector 131b inside the housing 11 and the control unit 12_1 or 12_2 mounted on the external connector 131c outside the housing 11.

The connection unit 13 is screwed to the wall portion of the housing 11, so that the packing 134 is pressed against the inner wall of the housing 11 to seal the opening 11op in a liquid-tight state. As a result, a liquid LQ can be prevented from leaking from inside the housing 11 to the outside via the opening 11op. In addition, by pressing the packing 134 against the connector 131, the liquid LQ can be prevented from leaking from inside the housing 11 to the outside through the substrate 131a.

Next, a control method of the liquid immersion device 1 according to the present embodiment will be described.

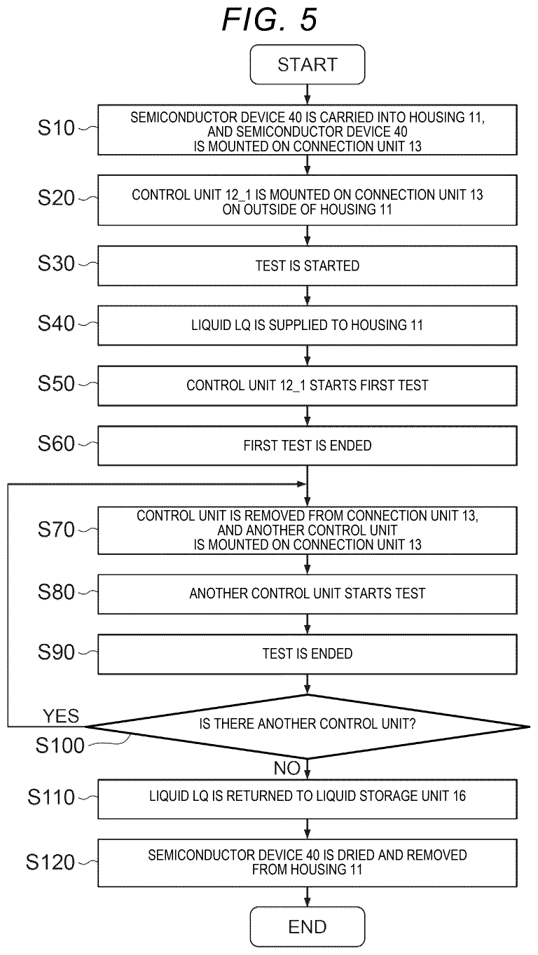

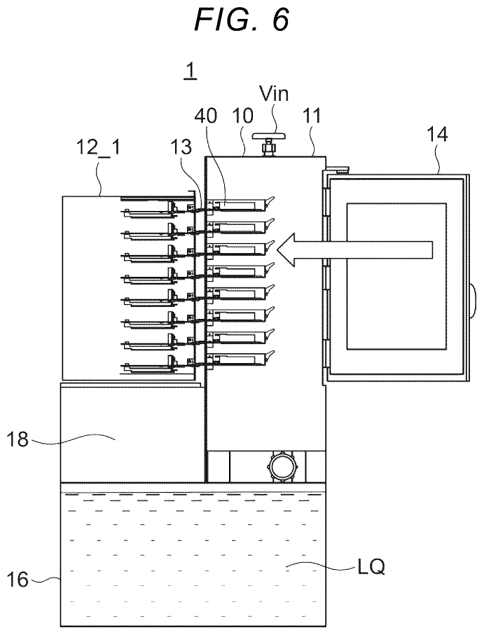

FIG. 5 is a flowchart showing an example of the control method of the liquid immersion device according to the first embodiment. FIGS. 6 to 13 are cross-sectional views showing an example of the control method of the liquid immersion device according to the first embodiment. Hereinafter, a test of the semiconductor device 40 will be described as an example of the control. In FIGS. 6 to 13, the temperature control unit 20 is not shown.

First, as shown in FIG. 6, the operator opens the door 14 of the liquid immersion device 1, carries a plurality of semiconductor devices 40 into the housing 11, and mounts the plurality of semiconductor devices 40 on the connection unit 13 (step S10). The operator mounts the control unit 12_1 on the connection unit 13 on the outside of the housing 11 (step S20). The control unit 12_1 may be mounted on the connection unit 13 before mounting the semiconductor device 40, and may be mounted on the connection unit 13 until the test is started. In addition, at this time, the liquid LQ is still accommodated in the liquid storage unit 16 and is not supplied to the housing 11.

The operator closes the door 14 and causes the controller 18 to start the test (step S30). A test start unit by the operator is not limited, and a start button may be displayed on a touch panel (not shown) or the like, or a start switch may be provided in the liquid immersion device 1.

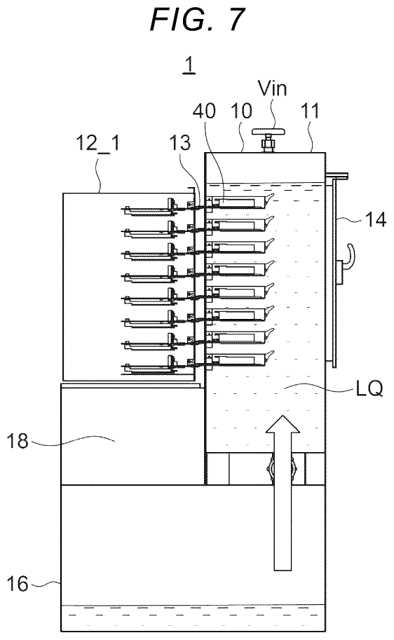

When the test is started, the controller 18 controls the pump 17 (see FIG. 3) to supply the liquid LQ in the liquid storage unit 16 to the housing 11 as shown in FIG. 7 (step S40). At this time, the controller 18 opens the valve Vin while keeping the valves Vout and Vc closed. The pump 17 sends the liquid LQ into the housing 11 via the pipe 15. As a result, as shown in FIG. 7, the semiconductor device 40 is immersed in the liquid LQ. The controller 18 may measure the height of the liquid surface of the liquid LQ in the housing 11 by using an electrical or optical sensor (not shown), and automatically detect whether the semiconductor device 40 is immersed in the liquid LQ.

When the semiconductor device 40 is immersed in the liquid LQ, the controller 18 causes the control unit 12_1 to start the test. The control unit 12_1 starts the test (first test) of the semiconductor device 40 under the control of the controller 18 (step S50). For example, the test is a test for checking an electrical operation of the semiconductor device 40 or a test for checking a function of the semiconductor device 40 in a heating environment or a cooling environment. When controlling the temperature of the semiconductor device 40, the controller 18 opens the valve Vc and circulates the liquid LQ between the housing 11 and the temperature control unit 20. More specifically, the test may be a functional test such as a write operation of test data, a read operation, a memory capacity, or a communication function of an input/output unit. In addition, the test may be a functional test under a high temperature environment. In this case, the temperature control unit 20 heats the liquid LQ in the housing 11 to a predetermined temperature. Conversely, the test may be a functional test under a low temperature environment. In this case, the temperature control unit 20 cools the liquid LQ in the housing 11 to a predetermined temperature. Furthermore, the test may be a thermal cycle test in which the function is tested by repeating the low temperature and the high temperature. In this case, the temperature control unit 20 controls the temperature of the liquid LQ in the housing 11. The control unit 12_1 is configured to be capable of executing at least one of the tests on the semiconductor device 40. For example, the control unit 12_1 may be configured with a CPU and a program, or may be configured with a logic circuit such as a programmable logic controller (PLC).

When the first test by the control unit 12_1 is ended (step S60), the controller 18 notifies the operator that the control unit 12_1 is exchangeable. A notification unit to the operator is not limited, and the information may be displayed on a monitor (not shown) or may be notified by voice.

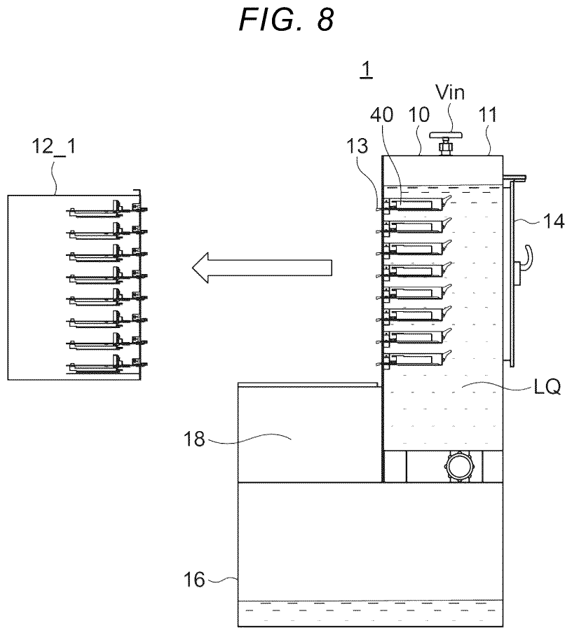

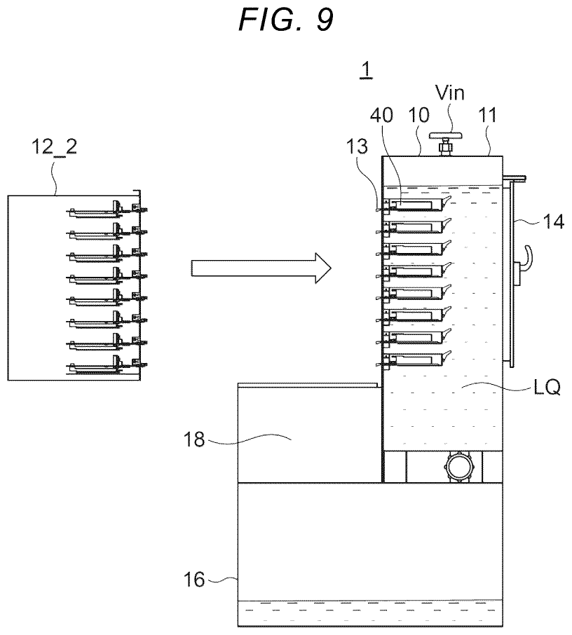

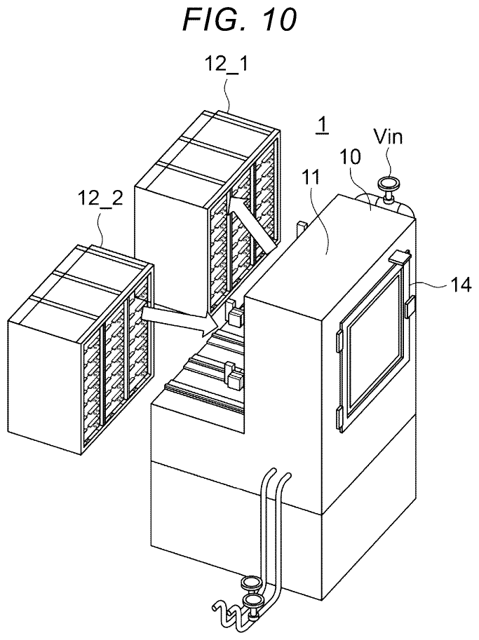

Next, as shown in FIG. 8, the operator detaches the control unit 12_1 from the connection unit 13 outside the housing 11, and as shown in FIG. 9, mounts the control unit 12_2 on the connection unit 13 (step S70). That is, as shown in FIG. 10, the operator exchanges the control unit 12 mounted on the connection unit 13. The control unit 12_2 is configured to be capable of executing at least one of the tests on the semiconductor device 40, and executes a test (second test) different from the test (first test) of the control unit 12_1. For example, the control unit 12_2 may be configured with a CPU and a program, or may be configured with a logic circuit such as a PLC.

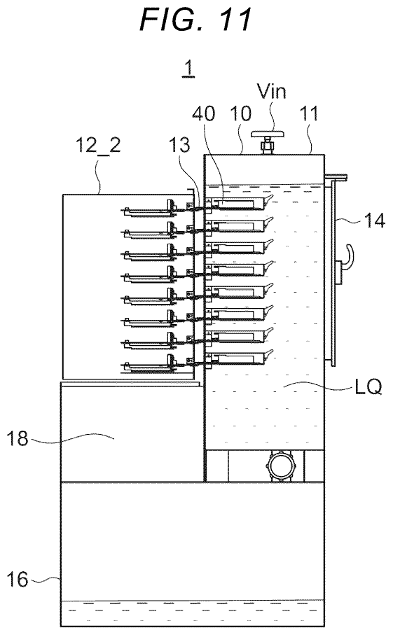

As shown in FIG. 11, when the exchange from the control unit 12_1 to the control unit 12_2 is ended, the operator causes the controller 18 to start the test. At this time, the housing 11 is filled with the liquid LQ, and the semiconductor device 40 is already immersed in the liquid LQ. Therefore, the controller 18 can start the test immediately after the exchange of the control unit 12_1. The control unit 12_2 starts the test (second test) of the semiconductor device 40 under the control of the controller 18 (step S80).

When the second test by the control unit 12_2 is ended (step S90), the controller 18 notifies the operator that the control unit 12_2 is exchangeable. When another control unit 12 is provided (YES in step S100), the steps S70 to S90 are repeated.

When other control unit 12 is not provided (NO in step S100), the test of the semiconductor device 40 is ended. In this case, for example, the operator presses a test end button.

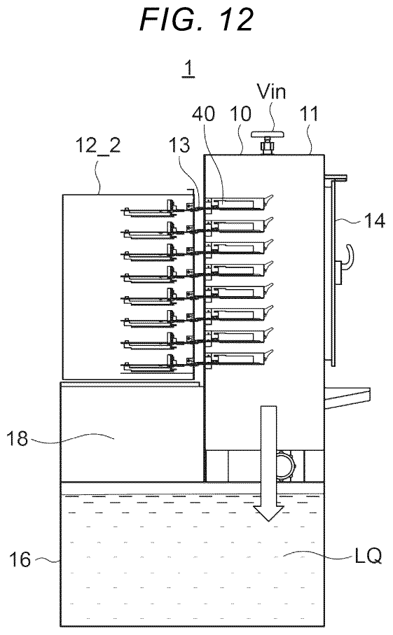

When the test is ended, the controller 18 returns the liquid LQ from the housing 11 to the liquid storage unit 16, as shown in FIG. 12. At this time, the controller 18 closes the valves Vin and Vc shown in FIG. 1, opens the valve Vout, and returns the liquid LQ in the housing 11 to the liquid storage unit 16 via the internal pipe (step S110).

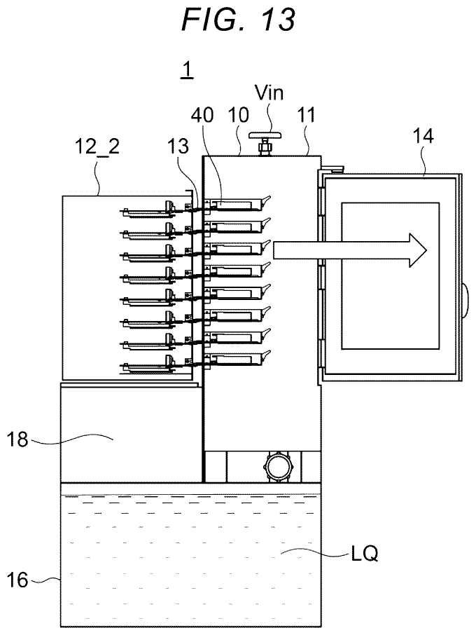

After the liquid LQ is returned from the housing 11 to the liquid storage unit 16, the controller 18 controls the blower BLW in FIG. 1 to blow the gas into the semiconductor device 40 in the housing 11. As a result, the liquid is removed and dried from the semiconductor device 40. Thereafter, as shown in FIG. 13, the operator opens the door 14, detaches the semiconductor device 40 in the housing 11 from the connection unit 13, and carries out the semiconductor device 40 from the housing 11 (step S120).

As a result, a series of tests of the semiconductor device 40 is ended.

As described above, the liquid immersion device 1 according to the present embodiment is configured such that the plurality of control units 12_1 and 12_2 are attachable and detachable in the outside of the housing 11, while the semiconductor device 40 is immersed in the liquid LQ inside the housing 11. The connection unit 13 penetrates the wall portion of the housing 11 in a liquid-tight state, and electrically connects the semiconductor device 40 immersed in the housing 11 and the control unit 12_1 or 12_2 on the outside of the housing 11. Therefore, the liquid immersion device 1 can execute a plurality of tests of different types on the semiconductor device 40 only by exchanging the plurality of control units 12_1 and 12_2 while maintaining a state in which the semiconductor device 40 is immersed in the housing 11.

Here, a comparative example is considered. A liquid immersion device of the comparative example can perform only one test for one device. Therefore, a plurality of liquid immersion devices are required to end a series of a plurality of tests. In this case, for each test, it is necessary to perform liquid immersion, drying, and transport operations such as drying the semiconductor device 40 from the liquid immersion state, removing the semiconductor device 40 from the housing 11, transporting the semiconductor device 40 to another liquid immersion device, and immersing the semiconductor device 40 again in the liquid immersion state.

On the other hand, according to the present embodiment, such a liquid immersion, drying, and transport operation may be performed only once when the semiconductor device 40 is removed from the housing 11 after the series of the plurality of tests is ended, and it is not necessary to perform the operation for each test. As a result, the burden on the operator can be reduced, and the test time can be shortened. In addition, the number of times of releasing the semiconductor device 40 from liquid immersion is reduced, and the opportunity for the operator to be exposed to the liquid is reduced.

In addition, according to the present embodiment, the same number of control units as the number of tests are required, and elements other than the control unit are common to the plurality of tests. As described above, according to the present embodiment, it is not necessary to use a test device that is different for each test, so that the installation area and the cost can be reduced.

In addition, according to the present embodiment, when the semiconductor device 40 is exchanged, the semiconductor device 40 is attached to and detached from the connection unit 13, and when the test is changed, the control units 12_1 and 12_2 are attached to and detached from the connection unit 13. The sockets of the connection unit 13 into which the semiconductor device 40 and the control units 12_1 and 12_2 are inserted and pulled out are different for the semiconductor device 40 and the control units 12_1 and 12_2 and are provided for each of the semiconductor device 40 and the control units 12_1 and 12_2. Therefore, since the test itself can be switched without inserting and pulling out the semiconductor device 40 as the test subject with respect to the connection unit 13, the number of times of inserting and pulling out the semiconductor device 40 with respect to the connection unit 13 is reduced. As a result, wear and deterioration of the connection unit 13 can be prevented. In other words, since the number of times of inserting and pulling out the connection unit 13 is distributed between the socket on the semiconductor device 40 side and the sockets on the control units 12_1 and 12_2 side, wear and deterioration of the connection unit 13 can be prevented. In addition, wear and deterioration of the connector of the semiconductor device 40 itself can also be prevented.

In addition, according to the present embodiment, the liquid storage unit 16 is provided in the liquid immersion device 1. The liquid storage unit 16 can store the liquid LQ for immersing the semiconductor device 40. As a result, when the semiconductor device 40 is carried into the housing 11 and carried out from the housing 11, it is not necessary to draw the liquid LQ to the outside of the liquid immersion device 1, and the semiconductor device 40 can be easily carried into and carried out.

In addition, according to the present embodiment, the blower BLW is provided in the housing 11. As a result, the blower BLW can dry the semiconductor device 40 without the operator coming into contact with the liquid LQ while the door 14 is closed.

In addition, since the temperature control unit 20 is provided, the temperature control of the semiconductor device 40 is facilitated through the liquid LQ.

The liquid immersion device 1 can be used not only for the test of the semiconductor device 40 but also for any other control. In this case, the control unit 12 may be changed to the control unit 12 for the control.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A liquid immersion device comprising:
a housing configured to accommodate a liquid and a semiconductor device immersed in the liquid;
a plurality of semiconductor device controllers provided on an outside of the housing and configured to control the semiconductor device; and
a connector that is attachably and detachably connected to the semiconductor device inside the housing, is attachably and detachably connected to any of the plurality of semiconductor device controllers outside the housing, and electrically connects the semiconductor device and one semiconductor device controller.

2. The liquid immersion device according to claim 1, wherein
a first semiconductor device controller of the plurality of semiconductor device controllers is selectively mounted on or detached from the connector,
in response to the first semiconductor device controller being mounted on the connector, the first device controller is configured to perform a first control of the semiconductor device, and
in response to the first semiconductor device controller being detached from the connector, a second semiconductor device controller of the plurality of semiconductor device controllers is mounted on the connector to perform a second control of the semiconductor device.

3. The liquid immersion device according to claim 2, wherein
the first control and the second control are a first test and a second test which are different from each other.

4. The liquid immersion device according to claim 3, wherein
the first test and the second test include a test of checking an electrical operation of the semiconductor device.

5. The liquid immersion device according to claim 3, wherein
the first test and the second test include a test of checking a function of the semiconductor device in a heating environment or a cooling environment.

6. The liquid immersion device according to claim 1, wherein
the connector includes a first adapter to which the semiconductor device is mounted inside the housing and a second adapter to which the plurality of semiconductor device controllers are mounted outside the housing, and
the connector penetrates a wall portion of the housing.

7. The liquid immersion device according to claim 6, further comprising:
a sealing material that seals between the connector and the wall portion of the housing, and between the first adapter and the second adapter in a liquid-tight state.

8. The liquid immersion device according to claim 1, wherein
the liquid is an insulating medium that cools or heats the semiconductor device.

9. The liquid immersion device according to claim 1, further comprising:
a storage that stores the liquid supplied to the housing or extracted from the housing; and
a pump that sends the liquid from the storage to the housing.

10. The liquid immersion device according to claim 1, further comprising:
a blower that is provided in the housing and blows gas into the semiconductor device after the liquid is extracted from the housing.

11. The liquid immersion device according to claim 1, further comprising:
a temperature controller that controls a temperature of the liquid in the housing.

12. A control method of a liquid immersion device that includes a housing configured to accommodate a liquid and a semiconductor device, a plurality of semiconductor device controllers provided on an outside of the housing, and a connector that is attachably and detachably connected to the semiconductor device inside the housing, is attachably and detachably connected to any of the plurality of semiconductor device controllers outside the housing, and electrically connects the semiconductor device and one semiconductor device controller, the control method comprising:
carrying the semiconductor device into the housing and mounting the semiconductor device on the connector;
mounting a first semiconductor device controller of the plurality of semiconductor device controllers on the connector outside the housing;
supplying the liquid into the housing and immersing the semiconductor device in the liquid;
performing a first control on the semiconductor device by using the first semiconductor device controller;
detaching the first semiconductor device controller from the connector outside the housing;
mounting a second semiconductor device controller of the plurality of semiconductor device controllers on the connector outside the housing; and
performing a second control, which is different from the first control, on the semiconductor device by using the second semiconductor device controller.

13. The control method of a liquid immersion device according to claim 12, further comprising:
detaching the second semiconductor device controller from the connector outside the housing;
mounting a third semiconductor device controller of the plurality of semiconductor device controllers on the connector outside the housing;
performing a third control, which is different from the second control, on the semiconductor device by using the third semiconductor device controller;
extracting the liquid from the housing after performing the third control; and
drying the semiconductor device by blowing gas into the semiconductor device.

14. A liquid immersion device comprising:
a housing configured to accommodate a liquid and a semiconductor device immersed in the liquid;
a plurality of semiconductor device controllers configured to control the semiconductor device;
a storage that stores the liquid supplied to the housing or extracted from the housing; and
a pump that sends the liquid from the storage to the housing.

15. The liquid immersion device according to claim 14, further comprising:
a temperature controller that controls a temperature of the liquid in the housing.

16. A liquid immersion device comprising:
a housing configured to accommodate a liquid and a semiconductor device immersed in the liquid, and that includes a door and a connector which attachably and detachably connects one semiconductor device controller configured to control the semiconductor device; and
a first semiconductor device controller of a plurality of the semiconductor device controllers provided facing the connector, wherein
the connector is provided on a side opposite to the door with respect to the housing.

17. The liquid immersion device according to claim 16, wherein
the first semiconductor device controller is selectively mounted on or detached from the connector,
in response to the first semiconductor device controller being detached from the connector, a second semiconductor device controller of the plurality of semiconductor device controllers is mounted on the connector.

18. The liquid immersion device according to claim 17, wherein
the first semiconductor device controller performs a first control on the semiconductor device, and
the second semiconductor device controller performs a second control, which is different from the first control, on the semiconductor device.

19. The liquid immersion device according to claim 16, further comprising:
a first storage that stores the liquid supplied to the housing or extracted from the housing, and is provided at a position lower than the housing.

20. The liquid immersion device according to claim 19, further comprising:
a second storage that is different from the first storage unit, wherein
the first storage stores a first liquid at a first temperature,
the second storage stores a second liquid at a second temperature different from the first temperature, and
the housing is configured to accommodate the first liquid and the second liquid.
